(19) United States
(12) Patent Application Publication
(10) Pub. No.: US 2015/0243663 A1
(43) Pub. Date: Aug. 27, 2015

(54) METHOD FOR MANUFACTURING SEMICONDUCTOR DEVICE AND DEVICE MANUFACTURED USING THE SAME

(71) Applicant: United Microelectronics Corp., Hsinchu (TW)

(72) Inventors: Ching-Wen Hung, Tainan City (TW); Chih-Sen Huang, Tainan City (TW); Jia-Rong Wu, Kaohsiung City (TW); Ching-Ling Lin, Kaohsiung City (TW)

(73) Assignee: United Microelectronics Corp., Hsinchu (TW)

(21) Appl. No.: 14/187,628

(22) Filed: Feb. 24, 2014

(51) Int. Cl. H01L 27/092; H01L 29/417; H01L 21/02; H01L 29/45; H01L 21/8238; H01L 21/285

(52) U.S. Cl. CPC H01L 27/0924; H01L 21/823828; H01L 21/823821; H01L 21/823814; H01L 21/823864; H01L 21/28518; H01L 21/02063; H01L 21/02068; H01L 29/458; H01L 29/41791

(57) ABSTRACT

A method for manufacturing a semiconductor device and a device manufactured using the same are provided. According to a dual silicide approach of the embodiment, a substrate having a first area with plural first metal gates and a second area with plural second metal gates is provided, wherein the adjacent first metal gates and the adjacent second metal gates are separated by an insulation. A dielectric layer is formed on the first and second metal gates and the insulation. The dielectric layer and the insulation at the first area are patterned by a first mask to form a plurality of first openings. Then, a first silicide is formed at the first openings. The dielectric layer and the insulation at the second area are patterned by a second mask to form a plurality of second openings. Then, a second silicide is formed at the second openings.

### BACKGROUND

1. Technical Field

The disclosure relates in general to a method for manufacturing a semiconductor device and device manufactured using the same, and more particularly to the method for manufacturing a semiconductor device using a dual silicide approach, thereby improving the electrical properties of the semiconductor device.

2. Description of the Related Art

Size of semiconductor device has been decreased for these years. Reduction of feature size, improvements of the rate, the efficiency, the density and the cost per integrated circuit unit are the important goals in the semiconductor technology. The electrical properties of the device have to be maintained even improved with the decrease of the size, to meet the requirements of the commercial products in applications. For example, the layers and components with damages or improper design, which have considerable effects on the electrical properties of the device, would be the important issues of the device for the manufacturers. Also, a qualified device requires sufficient low resistance to satisfy the electrical requirements.

### SUMMARY

The disclosure is directed to a method for manufacturing a semiconductor device and device manufactured using the same, which a dual silicide approach is adopted for improving the electrical properties of the semiconductor device.

According to the disclosure, a method for manufacturing a semiconductor device is provided. A substrate having a first area with plural first metal gates and a second area with plural second metal gates is provided, wherein the adjacent first metal gates and the adjacent second metal gates are separated by an insulation. A dielectric layer is formed on the first and second metal gates and the insulation. The dielectric layer and the insulation at the first area are patterned by a first mask to form a plurality of first openings. Then, a first silicide is formed at the first openings. The dielectric layer and the insulation at the second area are patterned by a second mask to form a plurality of second openings. Then, a second silicide is formed at the second openings.

According to the disclosure, a semiconductor device is provided, comprising a substrate having a first area with plural first fins and a second area with plural second fins, and an overlaying region comprising one pair of the adjacent first fin and the second fin, and said adjacent first fin and the second fin being isolated by an isolation; a first doping region formed on one of the first fins, and a second doping region formed on one of the second fins; a first silicide formed at the first doping region, and a second silicide formed at the second doping region; and a conductive material formed above the first doping region and the second doping region and said isolation at the overlaying region, and the conductive material contacting the first silicide and the second silicide on said adjacent first fin and the second fin at the overlaying region.

### BRIEF DESCRIPTION OF THE DRAWINGS

FIG. 1A-FIG. 1L illustrate a method for manufacturing a semiconductor device according to a first embodiment of the present disclosure.

FIG. 2 simply shows arrangements of the pitch split approach and the T2Tsplit approach.

FIG. 3A simply shows a top view of an inverter manufactured by the first embodiment of the present disclosure.

FIG. 3B shows a cross-sectional view of the inverter of FIG. 3A.

FIG. 3C illustrates a cross-sectional view along the cross-sectional lines AA and BB of the inverter of FIG. 3A.

FIG. 4A-FIG. 4K illustrate a method for manufacturing a semiconductor device according to the second embodiment of the present disclosure.

FIG. 5A simply shows a top view of an inverter manufactured by the second embodiment of the present disclosure.

FIG. 5B shows a cross-sectional view of the inverter of FIG. 5A.

FIG. 5C illustrates a cross-sectional view along the cross-sectional lines AA, BB and CC of the inverter of FIG. 5A.

FIG. 6A-FIG. 6H illustrate a method for manufacturing a semiconductor device according to the third embodiment of the present disclosure.

FIG. 7A is a top view of a SRAM manufactured by the embodied method of the disclosure.

FIG. 7B is a cross-sectional view of a portion of the SRAM of FIG. 7B.

### DETAILED DESCRIPTION

In the present disclosure, a method for manufacturing a semiconductor device is provided to improve the electrical properties of the device, such as solving the higher resistance of conventional PMOS. The method of the embodiment also simplifies the manufacturing process, such as process for integrating PMOS silicide into the device with NMOS and PMOS.

In the embodiments of the present disclosure, the first openings in the first area and the second openings in the second area are formed by two different masks, i.e. the first and second masks respectively. According to the embodiments, a NMOS area and a PMOS area are illustrated as the first area and the second area, respectively. The first and second silicides may comprise the same or different materials. According to the embodiments, the first and second silicides comprise different materials, such as TiSi for the first openings in the first area (ex: contact openings in the NMOS area) and NiSi for the second openings in the second area (ex: the contact openings in the PMOS area). It is noted that the details of the manufacturing method of the embodiments would be different, and could be modified and changed according to the selected materials of the components (ex: silicides) and the patterning procedures in practical applications.

Three embodiments are provided hereinafter with reference to the accompanying drawings for describing the related configurations and procedures, but the present disclosure is not limited thereto. It is noted that not all embodiments of the invention are shown. Modifications and variations can be made without departing from the spirit of the disclosure to meet the requirements of the practical applications. Thus, there may be other embodiments of the present disclosure which are not specifically illustrated. It is also important to point out that the illustrations may not be necessarily be drawn to scale. Thus, the specification and the drawings are to be regard as an illustrative sense rather than a restrictive sense.

<First Embodiment>

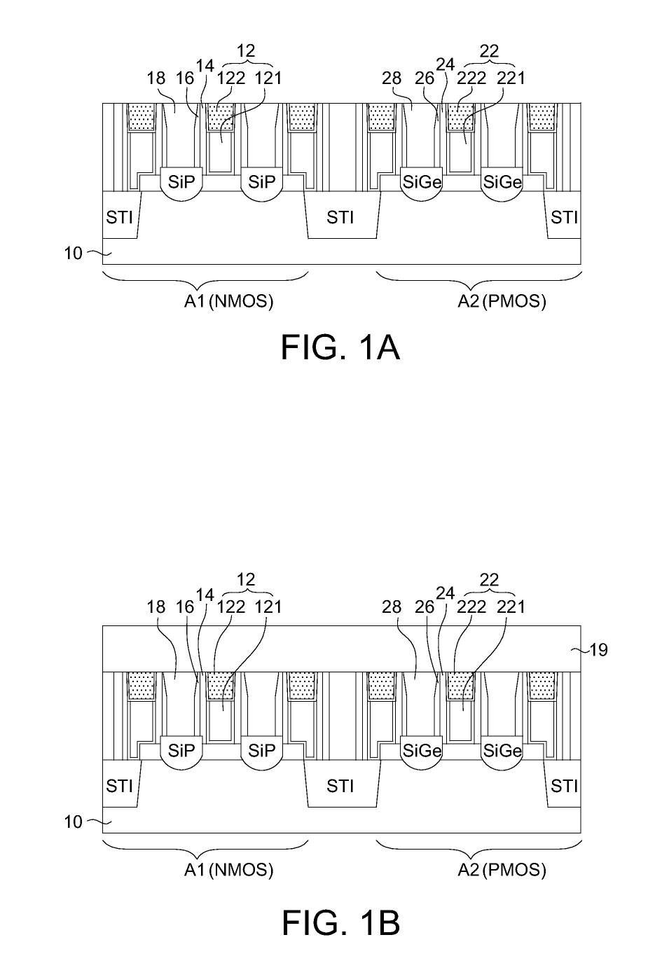

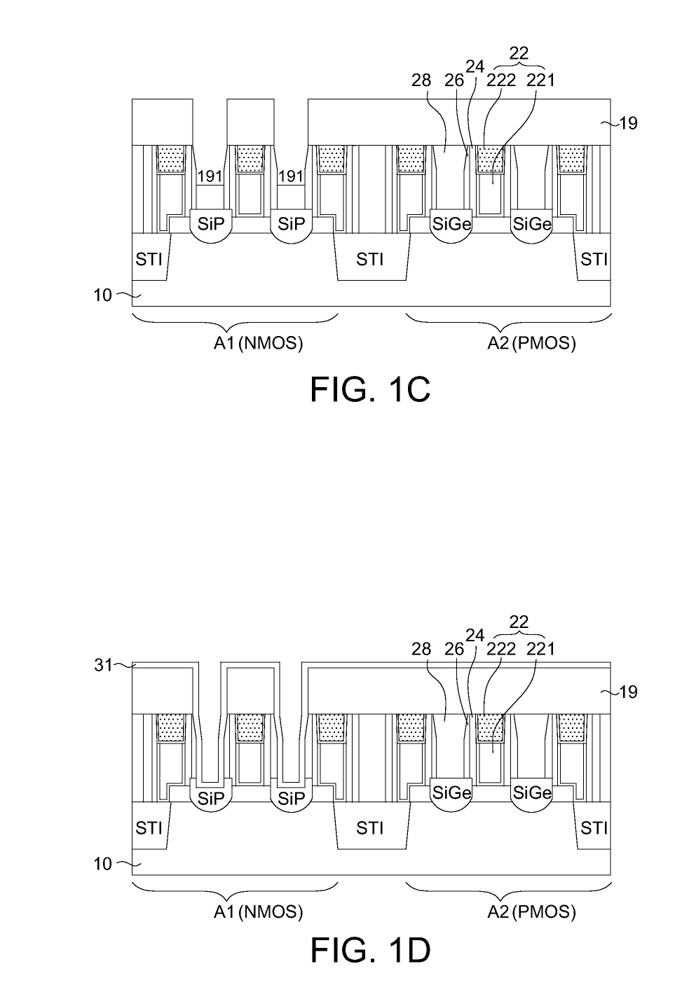

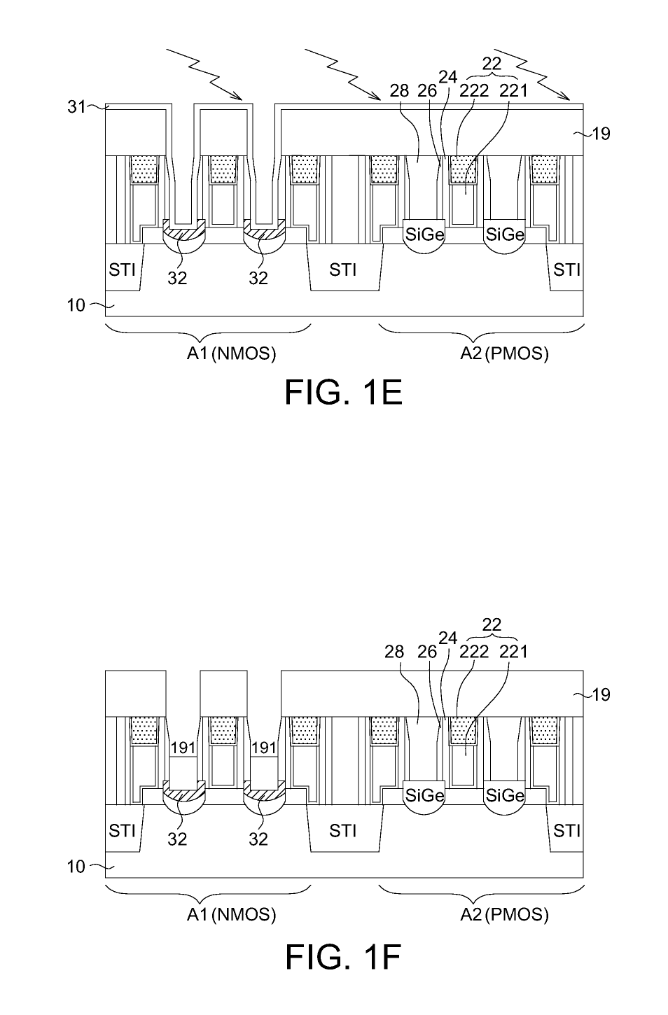

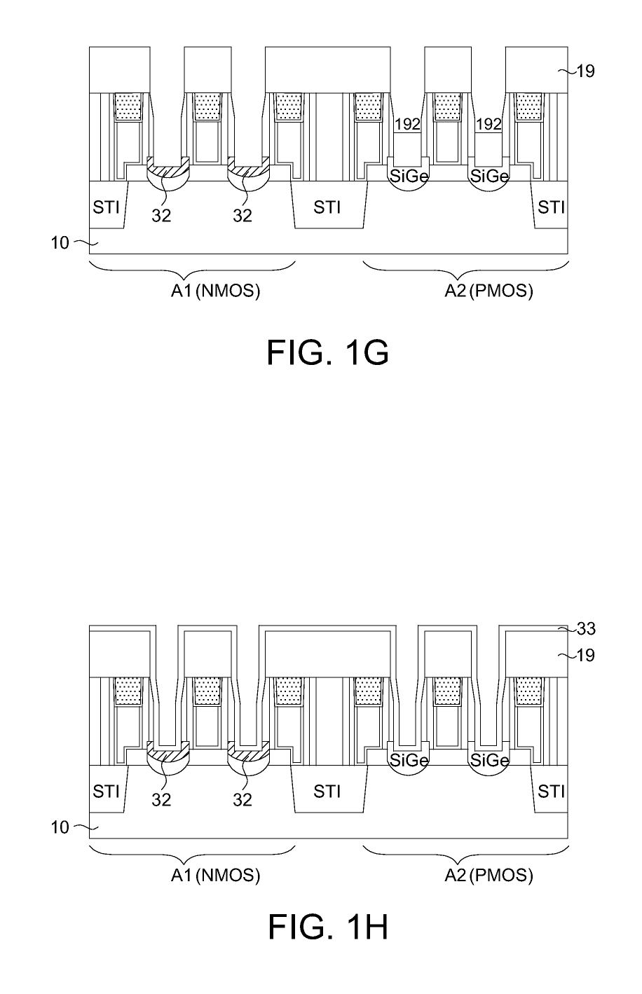

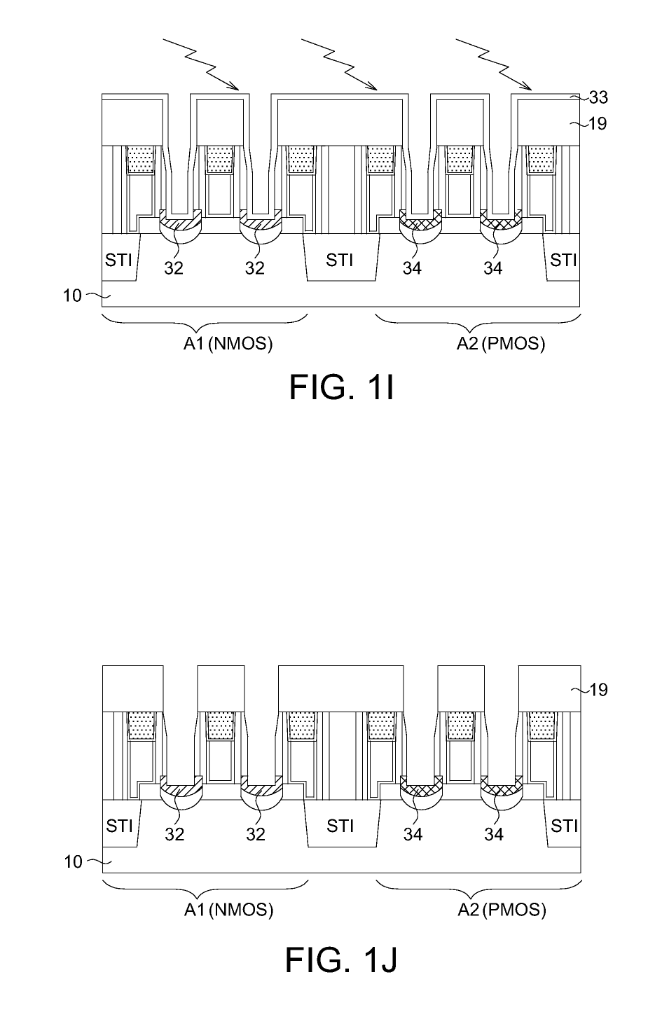

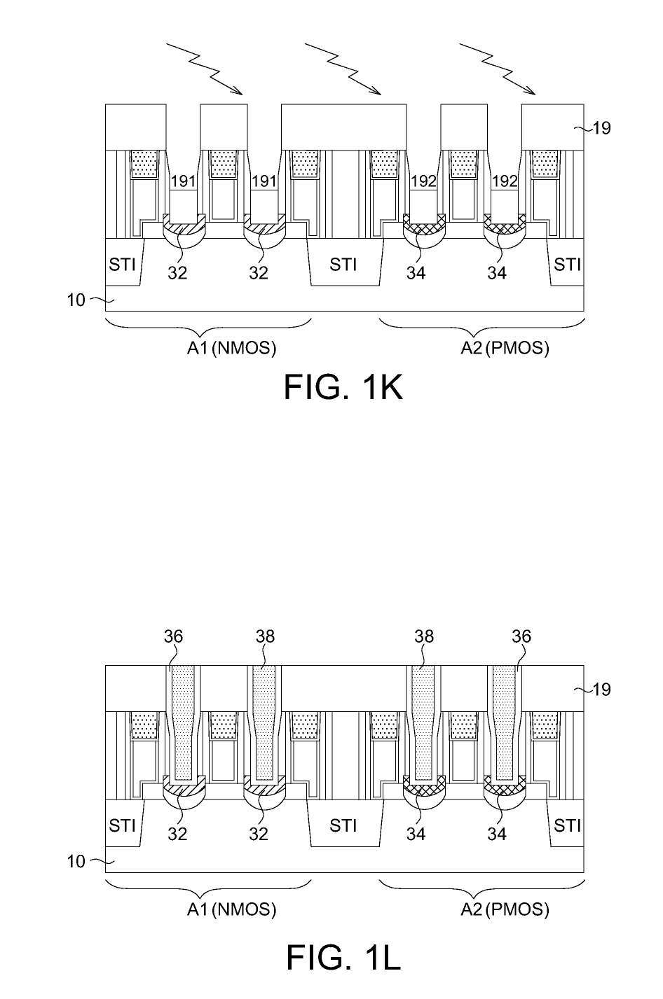

FIG. 1A-FIG. 1L illustrate a method for manufacturing a semiconductor device according to a first embodiment of the present disclosure. First, a substrate 10 having a first area A1 with plural first metal gates 12 and a second area A2 with plural second metal gates 22, wherein the adjacent first metal gates 12 and the adjacent second metal gates 22 are separated by an insulation, as shown in FIG. 1A. According to the embodiments, a NMOS area and a PMOS area are illustrated as the first area A1 and the second area A2, respectively.

In one embodiment, a RMG (replacement metal gate) process would have been done, and a first metal portion 121 and a first hard mask layer 122 on the first metal portion 121 constitute a first metal gate 12 in the first area A1 of the device, while a second metal portion 221 and a second hard mask layer 222 on the second metal portion 221 constitute a second metal gate 22 in the second area A2 of the device, as shown in FIG. 1A. Also, in each of the first and second areas A1 and A2, two spacers 14/24 are formed at the sidewalls of the first metal gate 12/the second m metal gate 22, and a contact etch stop layer (CESL) 16/26 is formed on the substrate 10 between the spacers 14/24. An interlayer dielectric (ILD) layer 18/28 fills into the space of the CESL 16/26. Accordingly, in each of the first and second areas Al and A2, the insulation for separating the adjacent metal gates 12/22 comprises the spacers 14/24, the CESL 16/26 and the ILD layer 18/28, as shown in FIG. 1A.

In one embodiment, the substrate 10 could be a silicon substrate, the spacers 14/24 and the CESL 16/26 could be made of the same material such as SICN, formed by atomic layer deposition (ALD). Also, the first hard mask layer 122 and the second hard mask layer 222 could be made of nitrite or oxide; for example, made of silicon nitrite (SIN). Also, the spacers 14/24 could be one layer or multi-layer, which are not limited particularly.

A dielectric layer 19 is then formed on the first metal gate 12 and the second metal gate 22 and the insulation (including the spacers 14/24, the CESL 16/26 and the ILD layer 18/28), as shown in FIG. 1B. The material of the dielectric layer 19 can be different from that of the first hard mask layer 122 and the second hard mask layer 222. The dielectric layer 19 can be (but not limited to) made of oxides, SiON, SiCN, or any suitable materials. In one embodiment, a thickness of the dielectric layer 19 is in a range of about 700 Å-about 1000 Å, such as about 850 Å; for example, about 850 Å of a PMD (pre-metal deposition) TEOS is deposited as the dielectric layer 19. But those values are not for limiting the scope of the disclosure.

Afterward, the procedures of contact patterning (ex: MOOT-PS1 patterning) and siliside formation (ex: NMOS siliside) in the first area A1 are performed first, followed by the procedures of contact patterning (ex: MOCT-PS2 patterning) and siliside formation (ex: PMOS siliside) in the second area A2. The details of the embodiment are described below.

As shown in FIG. 10, the dielectric layer 19 and the insulation in the first area A1 (ex: NMOS) are patterned by a first mask to form a plurality of first openings 191. Two of the first openings 191 are illustrated in the drawings, but the number of the first openings 191 would be determined depending on the actual needs of the practical applications. Also, in one embodiment, the first openings 191 in the first area A1 (ex: NMOS) are formed for exposing SiP at the substrate 10.

After forming the first openings 191, the substrate 10 and the first openings 191 could be subjected to a pre-clean treatment, such as a SiCoNi pre-clean treatment or an Ar pre-clean treatment, to clean the impurities (ex: native oxides).

Afterward, a first silicide 32 is formed at the first openings 191 in the first area A1. As shown in FIG. 1D, a Ti containing layer 31 (such as Ti/TiN) is deposited at the substrate 10 and within the first openings 191. The substrate 10 with the first openings 191 is then subjected to a first thermal treatment to form a Ti containing portion as the first silicide 32, as shown in FIG. 1E. According to the embodiment, the first silicide 32 is TiSi in the first area A1 (ex: NMOS). In one embodiment, the first thermal treatment is conducted at 650° C. (i.e. a first temperature) for about 10 seconds; but the procedure of the first thermal treatment can be modified according to the conditions of practical applications. Then, the unreacted Ti containing portion of the Ti containing layer 31 is removed, as shown in FIG. 1F.

Subsequently, the dielectric layer 19 and the insulation in the second area A2 (ex: PMOS) are patterned by a second mask to form a plurality of second openings 192, as shown in FIG. 1G. In one embodiment, the second openings 192 in the second area A2 (ex: PMOS) are formed for exposing SiGe at the substrate 10. Similarly, after forming the second openings 192, the substrate 10 and the second openings 192 could be subjected to a pre-clean treatment, such as a SiCoNi pre-clean treatment or an Ar pre-clean treatment, to clean the impurities (ex: native oxides).

Afterward, a second silicide 34 is formed at the second openings 192 in the second area A2. As shown in FIG. 1H, a Ni containing layer 33 (such as NiPt/TiN) is deposited at the substrate 10 and within the second openings 192. The substrate 10 with the second openings 192 is then subjected to a second thermal treatment to form a Ni containing portion as the second silicide 34, as shown in FIG. 11. According to the embodiment, the second silicide 34 is NiSi in the second area A2 (ex: PMOS). Then, the unreacted Ni containing portion of the Ni containing layer 33 is removed, as shown in FIG. 1J. In one embodiment, a first temperature of the first thermal treatment is higher than a second temperature of the second thermal treatment.

In one embodiment, the second thermal treatment for forming NiSi can be conducted by two steps. First, the substrate 10 with the second openings 192 is heated at 280° C. (i.e. a second temperature) for about 30 seconds. After the unreacted Ni containing portion of the Ni containing layer 33 is removed (FIG. 1J), the substrate 10 with the first silicide 32 in the first openings 191 and the second silicide 34 in the second openings 192 are further subjected to a third thermal treatment (ex: 450° C.) as shown in FIG. 1K, thereby decreasing the resistance(/resistivity) of the second silicide 34 (ex: transferring Ni₂Si to NiSi). In one embodiment, a third temperature of the third thermal treatment is higher than a second temperature of the second thermal treatment, but lower than a first temperature of the first thermal treatment. However, it is noted that the procedure of the second and third thermal treatments can be modified according to the conditions of practical applications.

After formations of the first silicide 32 in the first openings 191 and the second silicide 34 in the second openings 192, a barrier layer 36 is formed at the surfaces of the first openings 191 and the second openings 192 as a liner, and a conductive material (such as tungsten, W) is deposited on the substrate 10 and filling the first openings 191 and the second openings 192, followed by planarizing the conductive material (ex: CMP) to form the conductors 38, as shown in FIG. 1L. FIG. 1L also shows that the first silicide 32 and the second silicide 34 manufactured by the embodied method are substantially formed at the substrate 10, witch are also positioned at the same level.

According to the first embodiment, the first openings 191 in the first area A1 and the second openings 192 in the second area A2 are formed by two different masks, i.e. the first and second masks respectively. Also, the first silicide 32 and the second silicide 34 may comprise different materials (such as TiSi as the first silicide 32, and NiSi as the second silicide 34 is) for obtaining good electrical characteristics of the semiconductor device in the application. Additionally, the manufacturing method provided in the first embodiment simplifies the manufacturing process.

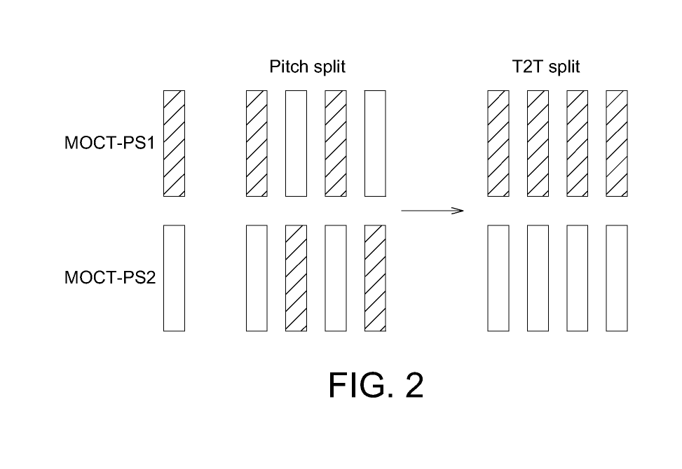

Moreover, instead of a pitch split approach adopted in the conventional manufacturing method, a T2Tsplit approach is adopted in the manufacturing method of the embodiment for creating the patterns of the first and second masks. FIG. 2 simply shows arrangements of the pitch split approach and the T2Tsplit approach. In FIG. 2, MOOT-PS1 represent the slits for patterning the contact at the NMOS area, and MOCT-PS2 represent the slits for patterning the contact at the PMOS area. According to the T2Tsplit approach, the pattern of MOOT-PS1 are arranged in parallel and aligned linearly (in rows), so does the pattern of MOCT-PS2. The T2Tsplit approach adopted in the manufacturing method of the embodiment solves the photo resist scumming issue.

According to one embodiment, the first mask comprises a first pattern having plural first splits corresponding to the first openings 191 of the first area A1, and the first splits are arranged in parallel and aligned linearly (in rows; such as the upper row in FIG. 2), while the second mask comprises a second pattern having plural second splits corresponding to the second openings 192 of the second area A2, and the second splits are arranged in parallel and aligned linearly (in rows; such as the lower row in FIG. 2).

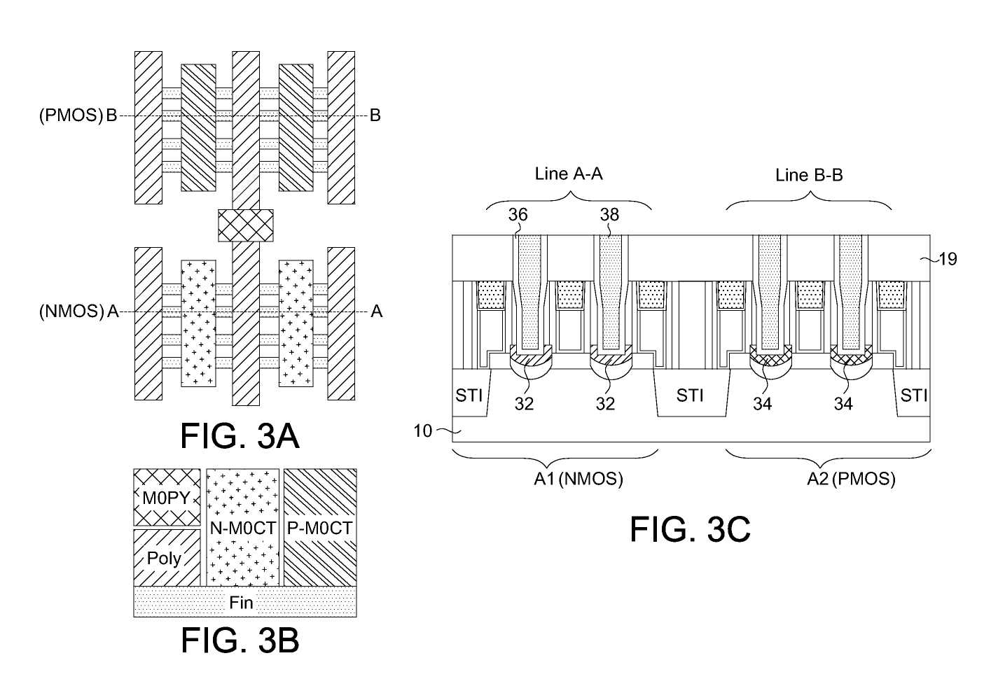

The manufacturing method the present disclosure is applicable to different semiconductor devices. An inverter is illustrated herein as one application. FIG. 3A simply shows a top view of an inverter manufactured by the first embodiment of the present disclosure. It is indicated in FIG. 3A that the T2Tsplit approach is adopted in the manufacturing method of the embodiment for solving the PR scumming issue. FIG. 3B shows a cross-sectional view of the inverter of FIG. 3A. FIG. 3C illustrates a cross-sectional view along the cross-sectional lines AA and BB of the inverter of FIG. 3A. The configuration of FIG. 3C is identical to that of FIG. 1L, and the details of the components are described above, which are not redundantly repeated.

<Second Embodiment>

According to the embodiments, the gate openings can be formed after or before forming the second silicide 34. In the first embodiment, the gate openings are formed after forming the second silicide 34. In the second embodiment, the gate openings are formed before forming the second silicide 34.

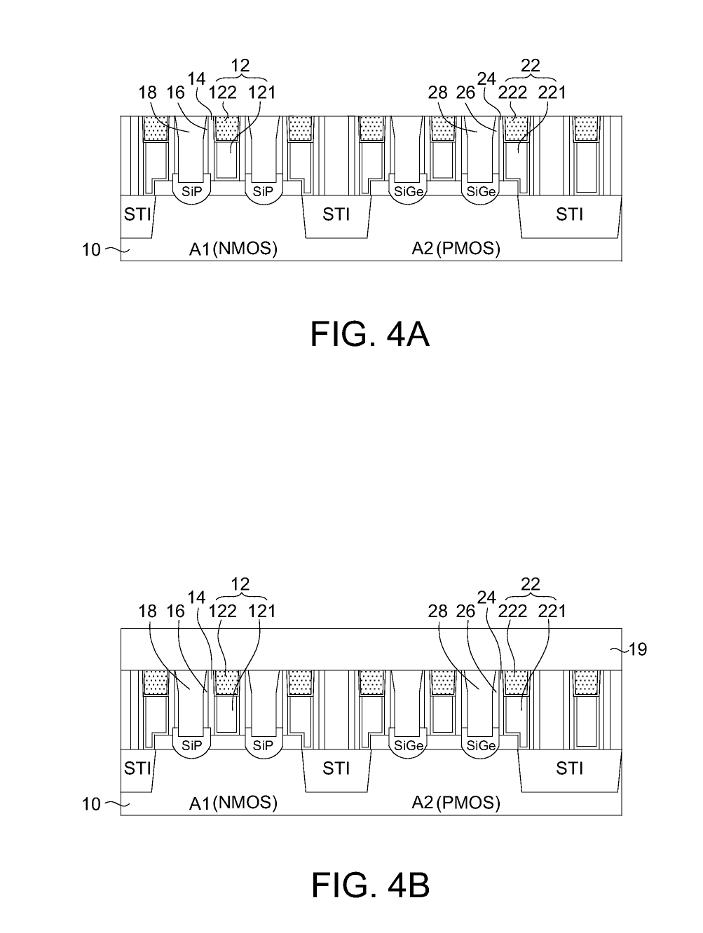

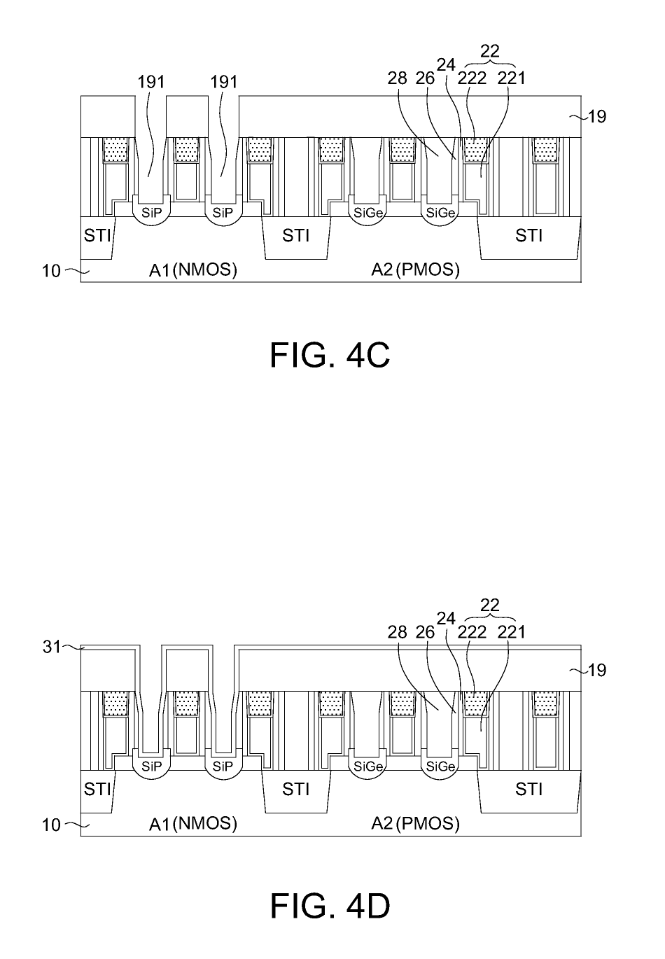

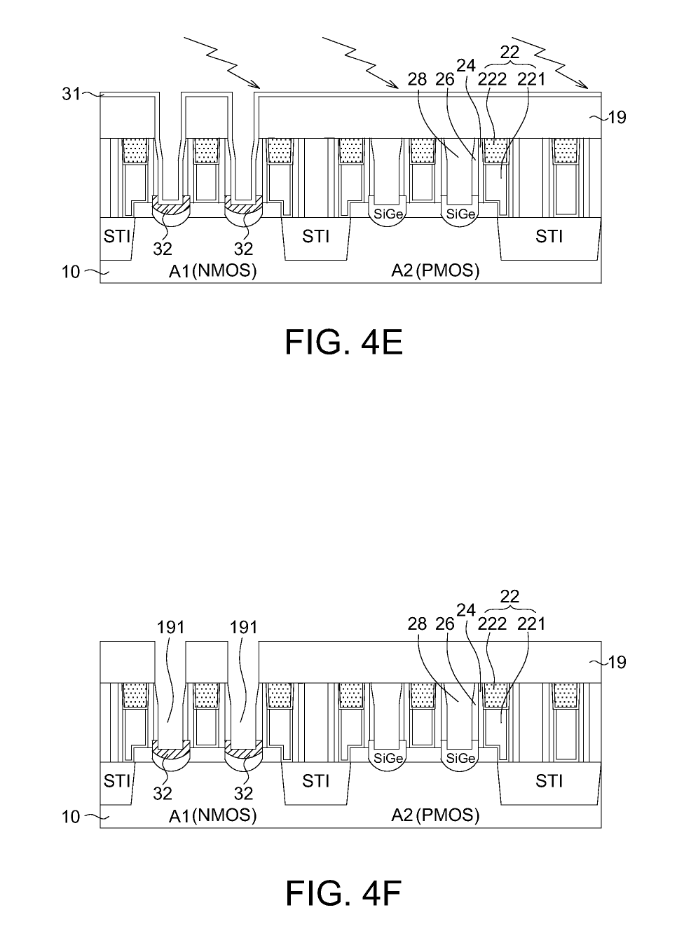

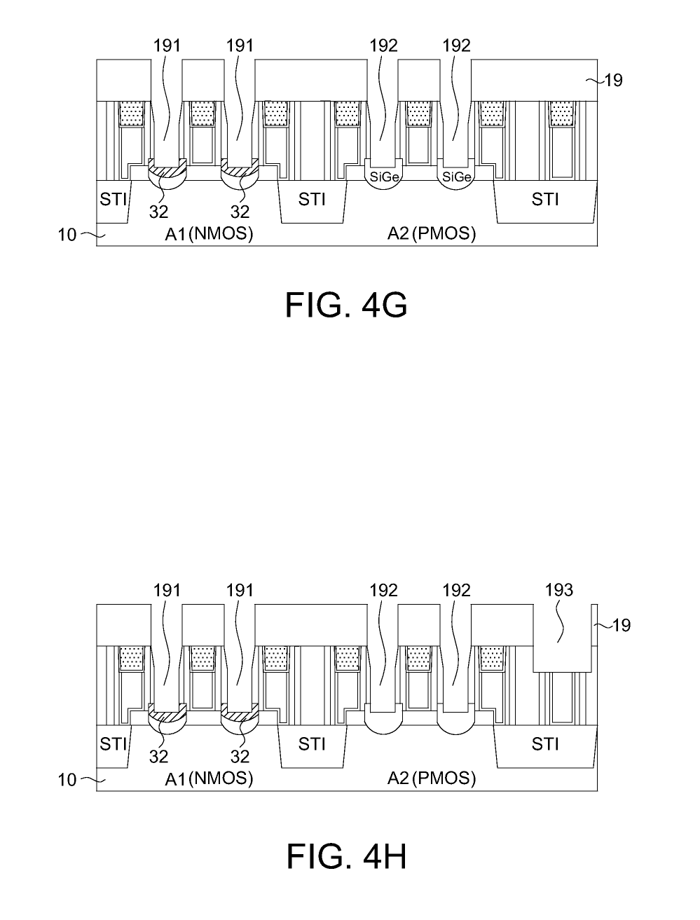

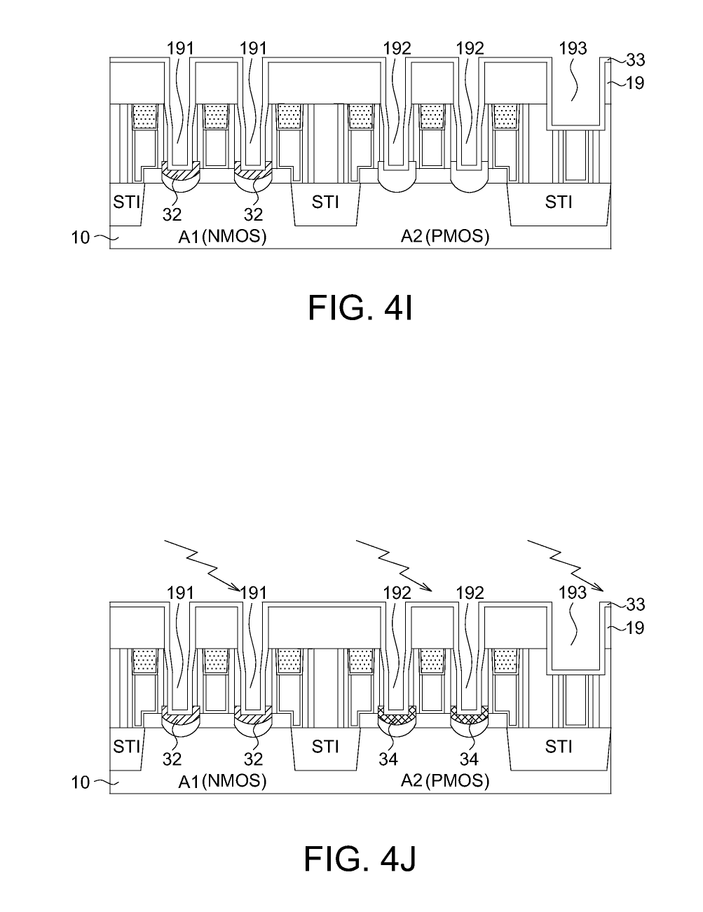

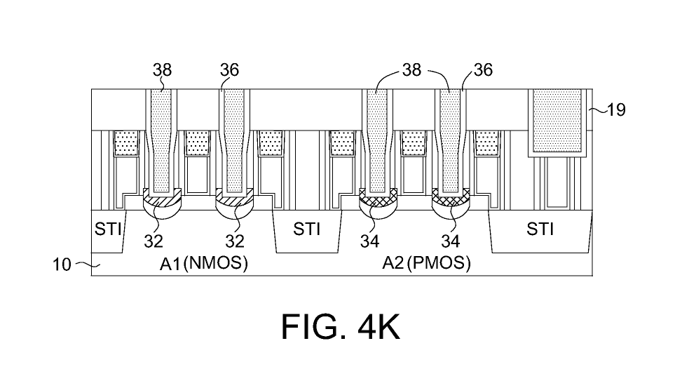

FIG. 4A-FIG. 4K illustrate a method for manufacturing a semiconductor device according to the second embodiment of the present disclosure. The identical elements of the first and second embodiments are designated with the same reference numerals. It is noted that steps as illustrated in FIG. 4A-FIG. 4G are identical to steps as illustrated in FIG. 1A-FIG. 1G. Please refer to the first embodiment for the descriptions of the related elements, and the details are not redundantly repeated.

After the first silicide 32 is formed at the first openings 191 in the first area A1 as shown in FIG. 4G, a plurality of gate openings 193 are formed (i.e. also named as the MOPY patterning) before forming the second silicide in the second embodiment. As shown in FIG. 4H, the gate openings 193 are formed.

Afterward, a second silicide 34 is formed at the second openings 192 in the second area A2. As shown in FIG. 41, a Ni containing layer 33 (such as NiPt/TiN) is deposited at the substrate 10, and the Ni containing layer 33 is formed within the first openings 191, the second openings 192 and the gate openings 193. The substrate 10 with the first openings 191, the second openings 192 and the gate openings 193 is then subjected to a second thermal treatment, so as to form a Ni containing portion as the second silicide 34 in the second openings 192, as shown in FIG. 4J. Also, the Ni containing portion deposited within the first openings 191 is formed on the first silicide 32.

According to the embodiment, the second silicide 34 is NiSi in the second area A2 (ex: PMOS). In one embodiment, a first temperature of the first thermal treatment is higher than a second temperature of the second thermal treatment.

In the first embodiment, the unreacted Ni containing portion of the Ni containing layer 33 is removed, as shown in FIG. 1J. However, there is no need to remove the unreacted Ni containing portion in the second embodiment. According to the method of the second embodiment, the unreacted Ni containing portion remains as a barrier layer 36 of the first openings 191, the second openings 192 and the gate openings 193.

After the first silicide 32 in the first openings 191, the second silicide 34 in the second openings 192 and the unreacted Ni containing portion as the barrier layer 36 are formed, and a conductive material (such as tungsten, W) is deposited on the substrate 10 and filling the first openings 191, the second openings 192 and the gate opening 193, followed by planarizing the conductive material (ex: CMP) to form the conductors 38, as shown in FIG. 4K.

According to the second embodiment, the first openings 191 in the first area A1 and the second openings 192 in the second area A2 are formed by two different masks, i.e. the first and second masks respectively. In the second embodiment, MOPY patterning is formed before the second silicide formation, so that it is no need to form a barrier layer (ex: Ti/TiN layer) in the first and second openings 191/192 before filling the conductive material (ex: tungsten (W)), since the unreacted TiN functions as a barrier layer. Similarly, the first silicide 32 and the second silicide 34 comprise different materials (such as TiSi as the first silicide 32, and NiSi as the second silicide 34 is) for obtaining good electrical characteristics of the semiconductor device in the application. Additionally, the manufacturing method provided in the second embodiment simplifies the manufacturing process.

Similarly, instead of a pitch split approach adopted in the conventional manufacturing method, a T2Tsplit approach as shown in FIG. 2 is adopted in the manufacturing method of the second embodiment for creating the patterns of the first and second masks. According to the T2Tsplit approach, the pattern of MOOT-PS1 are arranged in parallel and aligned linearly (in rows), so does the pattern of MOCT-PS2. The T2Tsplit approach adopted in the manufacturing method of the second embodiment solves the photo resist scumming issue.

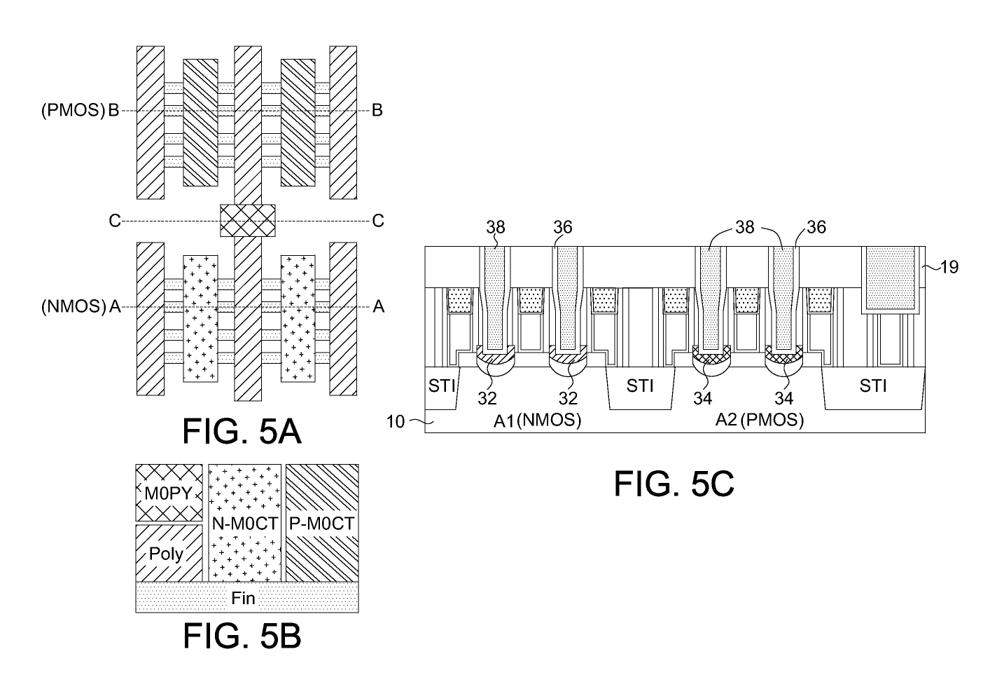

Similarly, an inverter is illustrated herein as one of the semiconductor devices applied by the second embodiment. FIG. 5A simply shows a top view of an inverter manufactured by the second embodiment of the present disclosure. It is indicated in FIG. 5A that the T2Tsplit approach is adopted in the manufacturing method of the second embodiment for solving the PR scumming issue. FIG. 5B shows a cross-sectional view of the inverter of FIG. 5A. FIG. 5C illustrates a cross-sectional view along the cross-sectional lines AA, BB and CC of the inverter of FIG. 5A. The configuration of FIG. 5C is identical to that of FIG. 4L, and the details of the components are described above, which are not redundantly repeated.

<Third Embodiment>

According to the third embodiment, the method further comprises step of pre-implantation before forming the silicides.

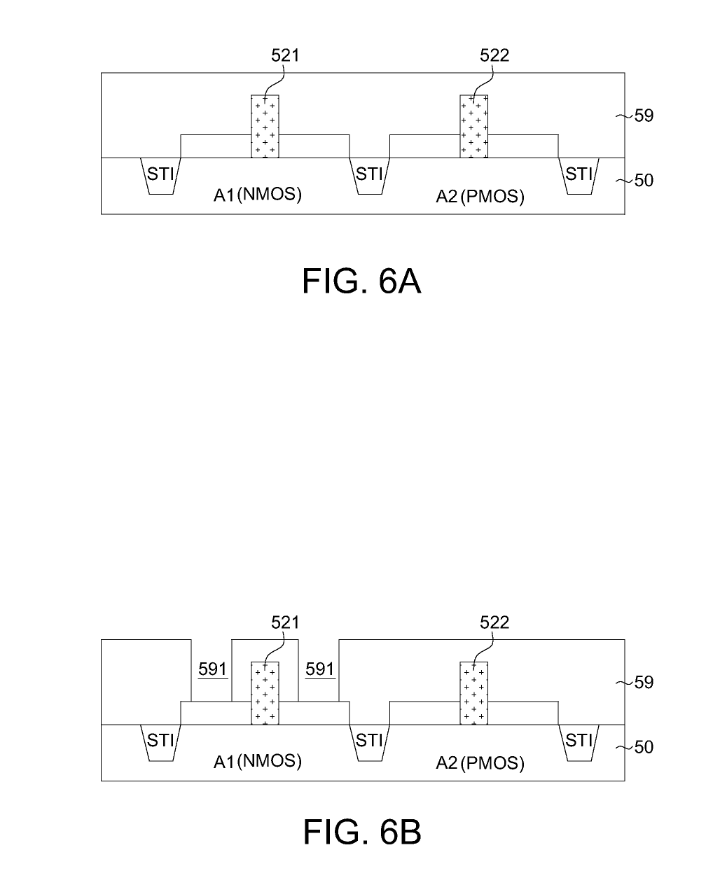

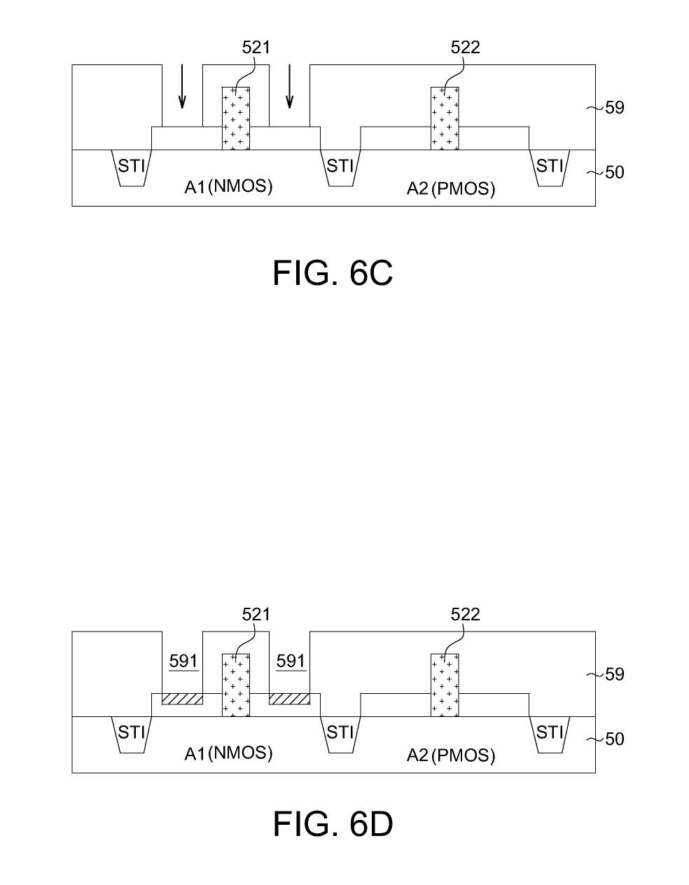

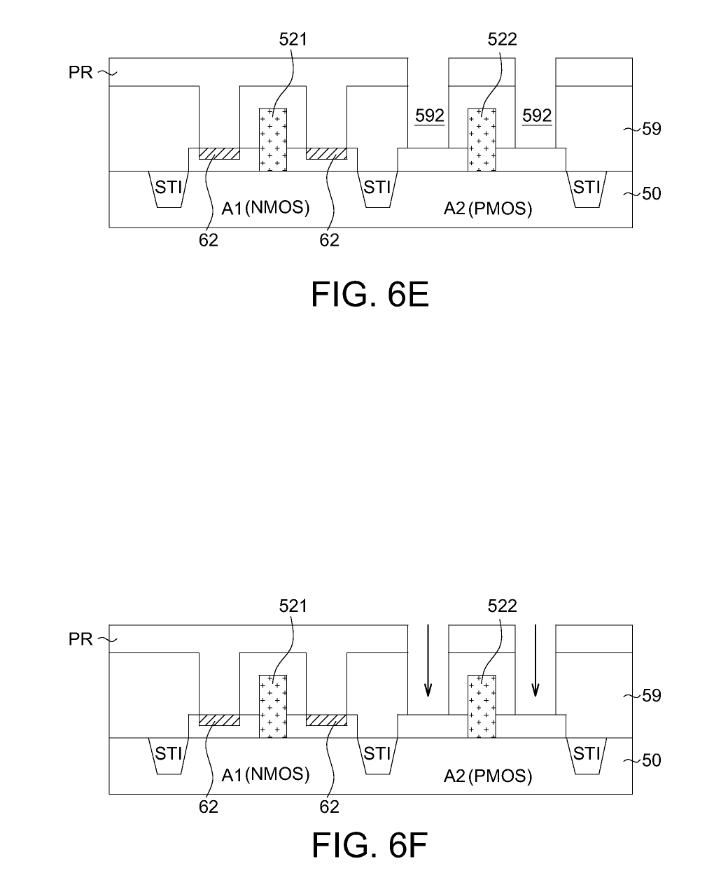

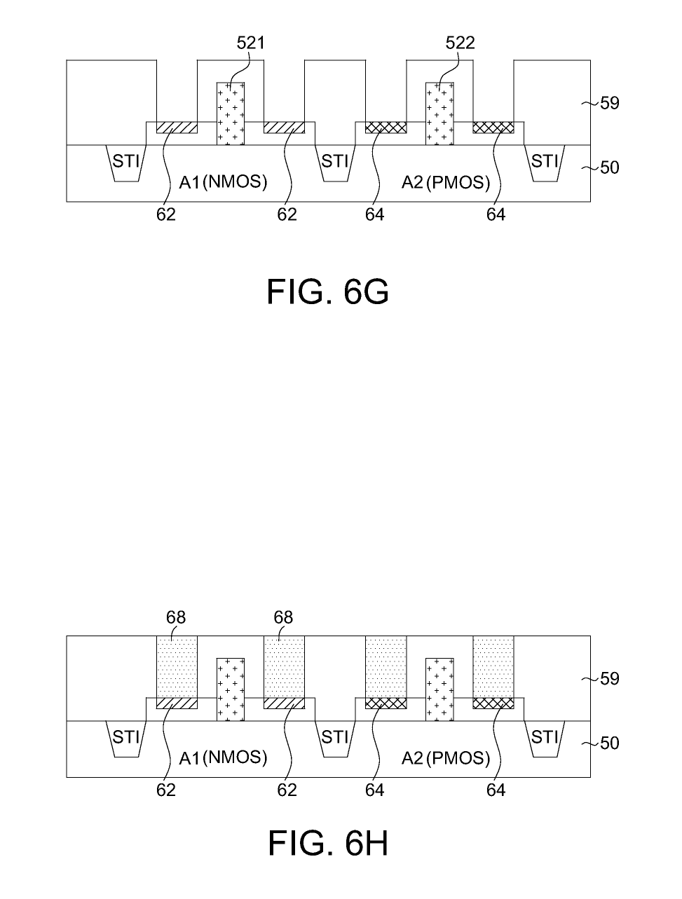

FIG. 6A-FIG. 6H illustrate a method for manufacturing a semiconductor device according to the third embodiment of the present disclosure. The similar elements of the third and first embodiments are designated with the similar reference numerals. Please also refer to the first embodiment for the descriptions of the related elements, and the details are not redundantly repeated.

First, a substrate 50 having a first area A1 with the first gate 521 and a second area A2 with the second gate 522 is provided, and a dielectric layer (such as an ILD layer) 59 is then formed on the first gate 521 and the second gate 522, as shown in FIG. 6A. According to the third embodiment, a NMOS area and a PMOS area are illustrated as the first area A1 and the second area A2, respectively. Also, the dielectric layer 59 can be (but not limited to) made of oxides, SiON, SiCN, or any suitable materials, depending on the requirement of the application.

As shown in FIG. 6B, the dielectric layer 59 in the first area A1 (ex: NMOS) is patterned by a first mask to form a plurality of first openings 591. Two of the first openings 591 are illustrated in the drawings, but the number of the first openings 591 would be determined depending on the actual needs of the practical applications.

Afterward, the first openings 591 are subjected to a first pre-implantation before forming the first silicide, as shown in FIG. 6C. In one embodiment, the first openings 591 are subjected to the first pre-implantation according to the first mask. Also, the first pre-implantation is N+ implantation for the first openings 591 formed correspondingly in the NMOS area.

Then, the first siliside 62 (ex: such as TiSi for being the NMOS siliside) is formed in the first openings 591 of the first area A1. Please refer to the descriptions of the first embodiment for the steps of forming the first siliside 62, and details are not repeated herein.

As shown in FIG. 6E, a PR layer is formed and patterned by a second mask to form a plurality of second openings 592.

Afterward, the second openings 592 are subjected to a second pre-implantation before forming the second silicide, as shown in FIG. 6F. In one embodiment, the second openings 592 are subjected to the second pre-implantation according to the second mask. Also, the second pre-implantation is P+ implantation for the second openings 592 formed correspondingly in the PMOS area.

Then, the second siliside 64 (ex: such as NiSi for being the PMOS siliside) is formed in the second openings 592 of the second area A2. Please refer to the descriptions of the first embodiment for the steps of forming the second siliside 64, and details are not repeated herein.

After the first silicide 62 in the first openings 591 and the second silicide 64 in the second openings 592 are formed (optionally, a barrier layer is formed), a conductive material (such as tungsten, W) is deposited on the substrate 50 and filling the first openings 591 and the second openings 592, followed by planarizing the conductive material (ex: using chemical-mechanical polishing (CMP) or other suitable planarization method) to form the conductors 68, as shown in FIG. 6H.

According to the third embodiment, the first openings 591 in the first area A1 and the second openings 592 in the second area A2 are formed by two different masks, i.e. the first and second masks respectively. Also, the method of the third embodiment further comprises step of pre-implantation before forming the silicides. The first silicide 32 and the second silicide 34 may comprise different materials (such as TiSi as the first silicide 32, and NiSi as the second silicide 34 is) for obtaining good electrical characteristics of the semiconductor device in the application. Additionally, the manufacturing method provided in the third embodiment simplifies the manufacturing process. Similarly, instead of a pitch split approach adopted in the conventional manufacturing method, a T2Tsplit approach as shown in FIG. 2 is adopted in the manufacturing method of the third embodiment for creating the patterns of the first and second masks, thereby solving the photo resist scumming issue.

<One of the applications-SRAM>

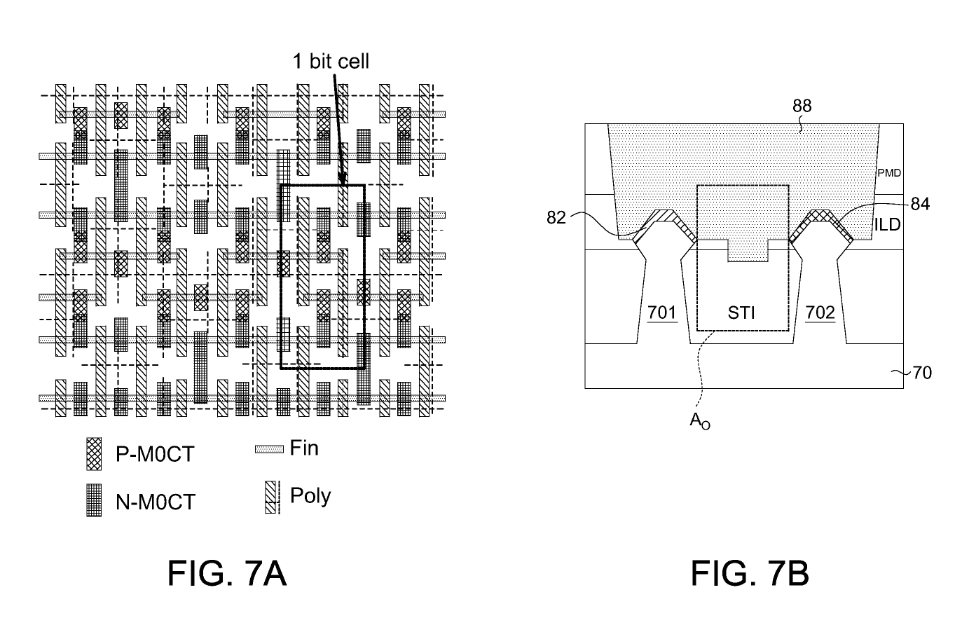

The manufacturing methods of the embodiment can be widely applied to different semiconductor devices. A SRAM (Static Random-Access Memory, SRAM) is illustrated herein as one of the applications. FIG. 7A is a top view of a SRAM manufactured by the embodied method of the disclosure. FIG. 7B is a cross-sectional view of a portion of the SRAM of FIG. 7B. Please refer to FIG. 7A and FIG. 7B.

In FIG. 7A, the area enclosed by the dashed line denotes one bit cell. As shown in FIG. 7B, the SRAM comprises a substrate 70 having a first area with plural first fins (such as N-fin) 701 and a second area with plural second fins (such as P-fin) 702, and an overlaying region Ao comprising one pair of the adjacent first fin 701 and the second fin 702, and said adjacent first fin 701 and the second fin 702 are isolated by an isolation (such as STI). Also, a first doping region (ex: S/D region), such as SiP for NMOS, is formed on the first fin 701, and a second doping region (ex: S/D region), such as SiGe for PMOS, is formed on the second fin 702. The SRAM comprises a first silicide (such as N-silicide) 82 formed at the first doping region, a second silicide 84 (such as P-silicide) formed at the second doping region, and a conductive material 88 formed above the first doping region and the second doping region and said isolation at the overlaying region Ao. The conductive material 88, such as tungsten (W), contacts the first silicide 82 and the second silicide 84 on the adjacent first fin 701 and the second fin 702 at the overlaying region Ao.

According to the aforementioned descriptions, the provided methods for manufacturing the semiconductor device of the embodiments adopt a dual silicide approach. The openings in the first area (such as NMOS area) and in the second area (such as PMOS area) are formed by two different masks. Also, different silicides, such as TiSi for the first openings (contact openings) in the NMOS area and NiSi for the second openings (contact openings) in the PMOS area, can be formed for improving the S/D external resistance (Rext) of the PMOS, thereby obtaining good electrical characteristics of the semiconductor device in the application consequently. In the embodiments, a T2Tsplit approach (as shown in FIG. 2) is adopted in the manufacturing method for creating the patterns of the first and second masks, thereby solving the photo resist scumming issue. Additionally, the manufacturing methods provided in the embodiments simplify the manufacturing process.

Other embodiments with different configurations of contacts, gates, (source and drain) are also applicable, which could be varied depending on the actual needs of the applications. It is, of course, noted that the configurations of FIG. 1L, FIG. 3A-FIG. 3C, FIG. 4L, FIG. 5A-FIG. 5C, FIG. 6H and FIG. 7 are depicted only for demonstration, not for limitation. It is known by people skilled in the art that the shapes or positional relationship of the constituting elements could be adjusted according to the requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing a semiconductor device, comprising:
providing a substrate having a first area with plural first metal gates and a second area with plural second metal gates, wherein the adjacent first metal gates and the adjacent second metal gates are separated by an insulation;
capping a dielectric layer on the first and second metal gates and the insulation;
patterning the dielectric layer and the insulation at the first area by a first mask to form a plurality of first openings;
forming a first silicide at the first openings;
patterning the dielectric layer and the insulation at the second area by a second mask to form a plurality of second openings; and
forming a second silicide at the second openings.

2. The method according to claim 1, wherein the first silicide is different from the second silicide.

3. The method according to claim 1, wherein the step of forming the first silicide comprises:
depositing a Ti containing layer at the substrate and within the first openings;
subjecting the substrate with the first openings to a first thermal treatment to form a Ti containing portion as the first silicide; and
removing an unreacted Ti containing portion.

4. The method according to claim 3, wherein the step of forming the second silicide comprises:
depositing a Ni containing layer at the substrate and within the second openings; and
subjecting the substrate with the second openings to a second thermal treatment to form a Ni containing portion as the second silicide; and
removing an unreacted Ni containing portion.

5. The method according to claim 4, wherein a first temperature of the first thermal treatment is higher than a second temperature of the second thermal treatment.

6. The method according to claim 4, wherein the substrate with the second silicide in second openings is further subjected to a third thermal treatment to decrease the resistance of the second silicide, wherein a third temperature of the third thermal treatment is higher than a second temperature of the second thermal treatment, but lower than a first temperature of the first thermal treatment.

7. The method according to claim 1, further comprising:
forming a plurality of gate openings after forming the second silicide.

8. The method according to claim 1, further comprising:
depositing a barrier layer at the surfaces of the first openings and the second openings as a liner; and
depositing a conductive material on the substrate and filling the first openings and the second openings; and
planarizing the conductive material.

9. The method according to claim 1, further comprising:
forming a plurality of gate openings before forming the second silicide.

10. The method according to claim 9, wherein the step of forming the second silicide comprises:
depositing a Ni containing layer at the substrate and within the first and second openings and the gate openings;
subjecting the substrate with the first and second openings and the gate openings to a second thermal treatment to form a Ni containing portion as the second silicide, wherein an unreacted Ni containing portion remains as a barrier layer of the second openings; and
filling a conductive material in the second openings.

11. The method according to claim 10, wherein the Ni containing portion deposited within the first openings is formed on the first silicide.

12. The method according to claim 1, further comprising:
subjecting the first openings to a first pre-implantation before forming the first silicide at the first openings.

13. The method according to claim 12, wherein the first openings are subjected to the first pre-implantation according to the first mask.

14. The method according to claim 12, further comprising:
subjecting the second openings to a second pre-implantation before forming the second silicide at the second openings.

15. The method according to claim 14, wherein the second openings are subjected to the second pre-implantation according to the second mask.

16. The method according to claim 14, wherein one of the first and second pre-implantations is N+ implantation, and the other is P+ implantation.

17. The method according to claim 1, wherein the first mask comprises a first pattern having plural first splits corresponding to the first openings of the first area, and the first splits are arranged in parallel and aligned linearly (in rows), while the second mask comprises a second pattern having plural second splits corresponding to the second openings of the second area, and the second splits are arranged in parallel and aligned linearly.

18. The method according to claim 1, wherein the insulation comprises:
spacers, formed at sidewalls of the metal gates;
a contact etch stop layer (CESL), formed at outsides of the spacers; and
a patterned ILD, formed between each space of adjacent portions of the CESL.

19. The method according to claim 1, wherein the substrate and the first openings and the second openings are subjected to a pre-clean treatment before forming the first silicide and the second silicide, respectively.

20. The method according to claim 1, wherein the first area is a NMOS area, and the second area is a PMOS area.

21. The method according to claim 1, wherein the first silicide and the second silicide are substantially formed at the substrate.

22. A semiconductor device, comprising:
a substrate having a first area with plural first fins and a second area with plural second fins, and an overlaying region comprising one pair of the adjacent first fin and the second fin, and said adjacent first fin and the second fin being isolated by an isolation;
a first doping region formed on one of the first fins, and a second doping region formed on one of the second fins;
a first silicide formed at the first doping region, and a second silicide formed at the second doping region; and
a conductive material formed above the first doping region and the second doping region and said isolation at the overlaying region, and the conductive material contacting the first silicide and the second silicide on said adjacent first fin and the second fin at the overlaying region.
